(19) United States
(12) Patent Application Publication
(10) Pub. No.: US 2010/0207271 A1
(43) Pub. Date: Aug. 19, 2010

(54) SEMICONDUCTOR DEVICE

(76) Inventor: Toshihiko Omi, Chiba-shi (JP)

Correspondence Address: Brinks Hofer Gilson & Lione/Seiko Instruments Inc., P.O. Box 10395, Chicago, IL, 60611, US

(21) Appl. No.: 12/707,348

(22) Filed: Feb. 17, 2010

(30) Foreign Application Priority Data
Feb. 19, 2009 (JP) JP2009-036590

(51) Int. Cl. H01L 23/488

(52) U.S. Cl. 257/737; 257/E23.023

(57) ABSTRACT

In order to provide a wafer level semiconductor device, a protection film and a stress buffer layer are formed on a metal wiring formed on a semiconductor element, a via-hole that passes through the protection film and the stress buffer layer is formed so as to expose the metal wiring, and a bump electrode is formed on a conductive layer that fills the via-hole.

### RELATED APPLICATIONS

This application claims priority under 35 U.S.C. §119 to Japanese Patent Application No. 2009-036590 filed on Feb. 19, 2009, the entire content of which is hereby incorporated by reference.

### BACKGROUND OF THE INVENTION

1. Field of the Invention

The present invention relates to a semiconductor device having a bump electrode, and more particularly, to a semiconductor device in which a wafer level packaging of a semiconductor element is formed.

2. Description of the Related Art

FIG. 5 is a cross sectional view illustrating a conventional wafer level packaging of a semiconductor element. The semiconductor element is packaged at a wafer level in the following manner. A metal terminal 4 for input/output that is formed of a metal wiring 3 and a protection film 5 for protecting the metal wiring 3 are formed on a semiconductor element 2, and the protection film 5 is etched so that a part of the metal terminal 4 for input/output is exposed, to thereby manufacture a semiconductor substrate 1. After that, a first stress buffer layer 21 is formed on the semiconductor substrate 1. Passing through the first stress buffer layer 21, a first open hole 23 is formed on the metal terminal 4 for input/output that is formed on the semiconductor substrate 1. Next, an underlying metal film is formed on an inner surface of the first open hole 23, on a surface of the metal terminal 4 for input/output, and on a surface of the first stress buffer layer 21. Using a photoresist, a pattern is formed for a rewiring 25 that electrically connects the first open hole 23 and a bump electrode 26 to be formed in a final step. Then, a metal such as copper is formed by, for example, plating so as to fill the first open hole 23 and an opening of the photoresist pattern for the rewiring 25.

Next, the photoresist formed for the pattern of the rewiring 25 is removed, and a part of the underlying metal film that is exposed by the removal of the photoresist is etched. Then, a second stress buffer layer 22 is formed on the first stress buffer layer 21 and the rewiring 25. Passing through the second stress buffer layer 22A, a second open hole 24 is formed on the rewiring 25. The bump electrode is formed in the second open hole 24 by screen printing or the like. In this manner, the wafer level packaging of the semiconductor element including the bump electrode is completed.

In general, a manufacturing process for a wafer level packaging of the semiconductor element having the structure as described above is complicated and long, causing a problem of a high manufacturing cost. Further, the rewiring that connects in plan view between the metal terminal for input/output and the bump electrode, which are disposed in the semiconductor wafer including the semiconductor element, is made of the metal formed by, for example, plating. Accordingly, arrangement of the rewiring is restricted, which affects a chip size of the semiconductor element.

JP 2006-165595 A discloses a structure, which is realized by a manufacturing process slightly simpler than the above-mentioned process, for a packaging of a semiconductor element used for a flip-chip or the like.

However, deforming stress of the bump electrode is easily transmitted to the semiconductor element, and hence the packaging of the semiconductor element may be susceptible to external mechanical stress since an open hole is formed in a central part of a bump electrode, and a conductive layer formed of a metal or the like is formed in the open hole in the structure disclosed in JP 2006-165595 A in packaging the semiconductor device.

Further, a manufacturing process for the wafer level packaging of the semiconductor element having the structure as described above is complicated and long, which causes a problem that a manufacturing cost is high. Further, since a rewiring that connects in plan view between a metal terminal for input/output and the bump electrode, which are arranged in a semiconductor wafer including the semiconductor element, is made of a metal formed by, for example, plating, arrangement of the rewiring is restricted, affecting a chip size of the semiconductor element.

### SUMMARY OF THE INVENTION

In view of the above, the present invention has an object to provide a wafer level packaging of a semiconductor element that is simple in manufacturing process and strong against an external mechanical stress.

In order to attain the above-mentioned object, the present invention provides a semiconductor device including: a semiconductor substrate including a semiconductor element and metal wirings formed on the semiconductor element; a protection film formed on a metal wiring in an uppermost layer of the metal wirings, for protecting the metal wiring; a stress buffer layer formed on the protection film; a via-hole formed on the metal wiring so as to pass through the protection film and the stress buffer layer; an underlying metal film formed on an inner surface of the via-hole, on a surface of the metal wiring, and on a surface of the stress buffer layer; a conductive layer formed so as to fill the via-hole; and a bump electrode formed on the conductive layer, in which the via-hole is formed, in plan view, at a peripheral position of the bump electrode.

The present invention also provides a semiconductor device including: a semiconductor substrate including a semiconductor element and metal wirings formed on the semiconductor element; a protection film formed on a wiring in an uppermost layer of the metal wirings, for protecting the metal wiring; a stress buffer layer formed on the protection film; a via-hole formed on the metal wiring so as to pass through the protection film and the stress buffer layer; an underlying metal film formed on an inner surface of the via-hole, on a surface of the metal wiring, and on a surface of the stress buffer layer; a conductive layer formed so as to fill the via-hole; a bump electrode formed on the conductive layer; a metal terminal for input/output formed of the metal wirings on the semiconductor element; and a rewiring that connects the metal terminal with the bump electrode and the conductive layer formed in the via-hole, in which the rewiring is formed of a second metal wiring formed below the protection film.

The present invention further provides the semiconductor device in which the stress buffer layer is one of a polyimide film and an organic resin film containing an epoxy as a base resin.

The present invention further provides the semiconductor device in which the stress buffer layer is an insulating ceramic film.

The present invention further provides the semiconductor device in which the stress buffer layer is the ceramic film containing one of aluminum oxide and aluminum nitride.

The present invention further provides the semiconductor device in which the stress buffer layer includes two layers including the ceramic film and a film made of a material having a mechanical rigidity lower than a mechanical rigidity of the ceramic film.

According to the present invention, a wafer level semiconductor device that is simple in manufacturing process and strong against external mechanical stress may be provided.

### BRIEF DESCRIPTION OF THE DRAWINGS

In the accompanying drawings:

FIG. 1 is a cross sectional view illustrating a first embodiment of the present invention;

FIG. 2 is a plan view illustrating the first embodiment of the present invention;

FIG. 3 is a cross sectional view illustrating a second embodiment of the present invention;

FIG. 4 is a plan view illustrating the second embodiment of the present invention; and

FIG. 5 is a cross sectional view illustrating a wafer level packaging of a semiconductor element having a conventional structure.

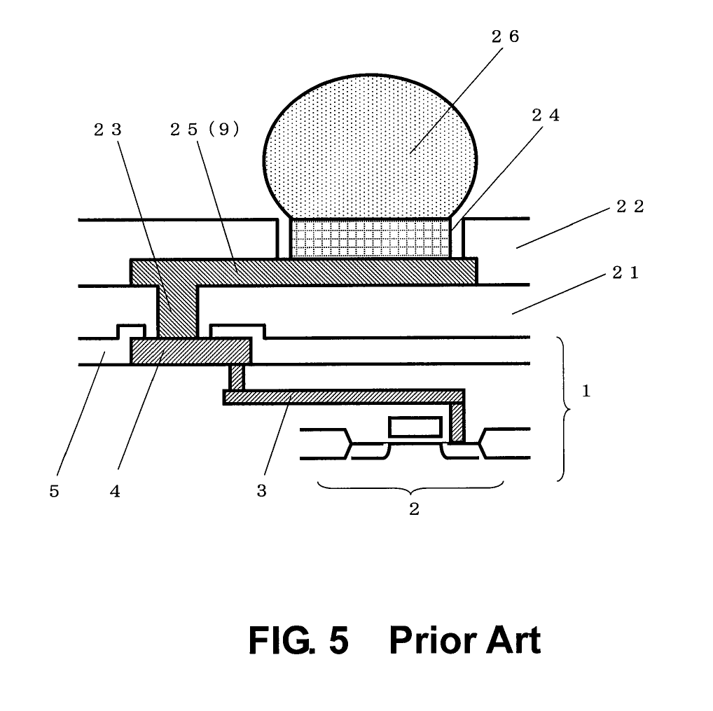

### DETAILED DESCRIPTION OF THE PREFERRED EMBODIMENTS

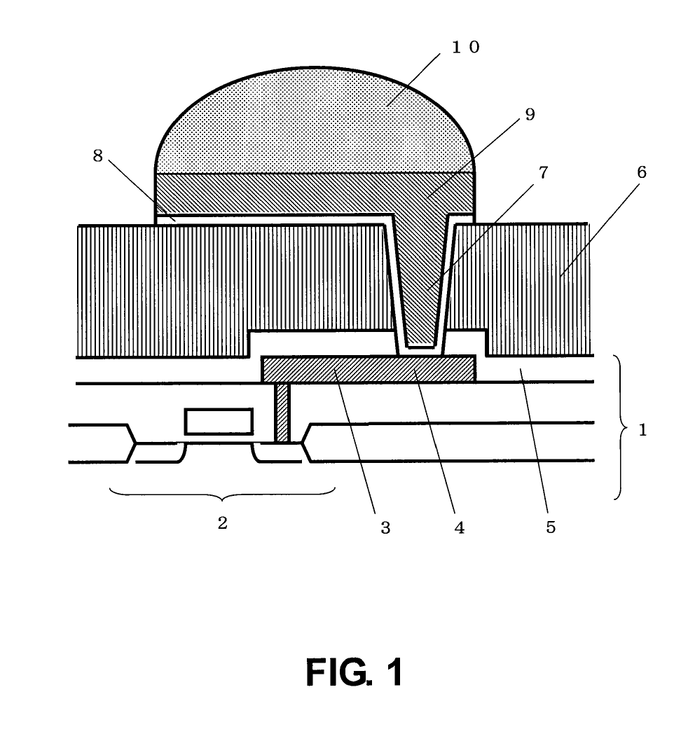

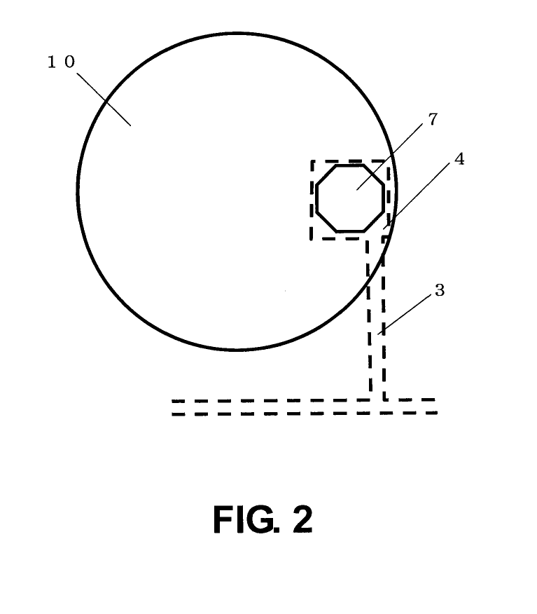

A first embodiment of the present invention is described below with reference to FIGS. 1 and 2.

A semiconductor element 2 that constitutes a complementary metal-oxide-semiconductor (CMOS) circuit is formed in a semiconductor substrate 1 made of p-type silicon. An input circuit or an output circuit of the CMOS circuit is connected to a metal terminal 4 for input/output via a metal wiring 3 made of aluminum. The metal wiring 3 and the metal terminal 4 for input/output in an uppermost layer are covered by a protection film 5 made of silicon nitride. It should be noted that the semiconductor substrate 1 may be made of n-type silicon.

Next, a stress buffer layer 6 is formed on the protection film 5. In this embodiment, for the stress buffer layer 6, a photosensitive polyimide film is formed by spin coating to a thickness of approximately 20 micrometers. After that, a portion of the polyimide film to be a via-hole 7 is exposed and developed using a photomask, and a hole to be the via-hole 7 is formed in the polyimide film. The via-hole 7 is located so as to avoid a central part of a bump electrode to be formed later, specifically, located in a peripheral region below the bump electrode. After that, the protection film 5 is etched by sulfur hexafluoride with the polyimide film being used as a mask, to thereby expose the metal wiring 3 at a bottom of the via-hole 7.

In the above description, the thickness of the stress buffer layer 6 is set to approximately 20 micrometers. Alternatively, the thickness thereof may be, for example, 10 micrometers or 30 micrometers.

Further, the stress buffer layer 6 is not necessarily made of polyimide. For example, a resin containing an epoxy as a base resin, such as PMMR or SU-8 has a similar function. Further, polyimide or the resin containing an epoxy as a base resin does not necessarily need to be photosensitive. For example, the following method may be employed instead. The protection film 5 is covered by, for example, a polyimide film, and then a surface of the polyimide film is covered by a metal film such as a chromium film. A photoresist is applied on the chromium film to be formed into a pattern for a via-hole in plan view by using a photomask. After that, the chromium film covering the surface of the polyimide film is processed by etching into the pattern for the via-hole in plan view. The photoresist is removed, and then the chromium film is used as a mask for etching, to thereby process the polyimide film into a shape of the via-hole. Alternatively, the following method may also be employed. The protection film 5 is covered by a polyimide film, and then the polyimide film is half cured. A photoresist is applied on the half-cured polyimide film. Exposure and development are performed to form a pattern for a via-hole in the photoresist and the polyimide film simultaneously. After that, the photoresist is removed, and the via-hole is formed in the polyimide film.

Further, a ceramic film may be used for the stress buffer layer 6. In particular, aluminum oxide, aluminum nitride, and the like are effective in terms of dissipation of heat generated in the semiconductor element to the outside because the thermal conductivity thereof is higher than that of a resin such as polyimide. Since the mechanical strength of the ceramic film is, in addition, higher than that of the resin, it might be concluded that the ceramic film has a high usefulness for a material of a wafer level packaging.

The ceramic film may be formed by, for example, laminating ceramic fine particles on the surface of the protection film 5.

In the case of using the ceramic film for the stress buffer layer 6, the ceramic film may be formed directly on the protection film 5. Alternatively, the protection film 5 may be first covered by a resin, such as polyimide, having a mechanical rigidity lower than that of ceramics, and then the ceramic film may be formed thereon.

After the stress buffer layer 6 and the via-hole 7 are formed, an underlying metal film 8 made of titanium/tungsten and copper is formed by sputtering on a surface of the stress buffer layer 6, on an inner surface of the via-hole 7, and on the metal wiring 3 exposed at the bottom of the via-hole 7. After that, a photoresist is formed by spin coating on a surface of the underlying metal film 8. A part of the photoresist in a region in which a bump electrode 10 is to be formed is removed by exposure and development using a photomask, to thereby expose the underlying metal film 8. After that, copper is deposited by electrolytic plating on an exposed part of the underlying metal film (underlying electrode) 8 to form a conductive layer 9. Next, a solder having a thickness of approximately 60 micrometers is formed by plating on the conductive layer 9 made of copper to serve as the bump electrode 10. Finally, the photoresist is dissolved and removed by an organic solvent, and then another part of the underlying metal film 8 exposed on the surface at this time is removed by etching to expose the stress buffer layer 6 in a region in which the bump electrode 10 is not formed. In this manner, the semiconductor device is completed. When the structure of this embodiment is observed from the top, as illustrated in FIG. 2, the via-hole 7 is located in a peripheral region below the bump electrode 10.

The first embodiment describes the case where the metal terminal 4 for input/output is located immediately below the bump electrode 10. However, a metal terminal for input/output is not necessarily located immediately below a peripheral region of a bump electrode. A position required for the bump electrode is possibly away from the metal terminal.

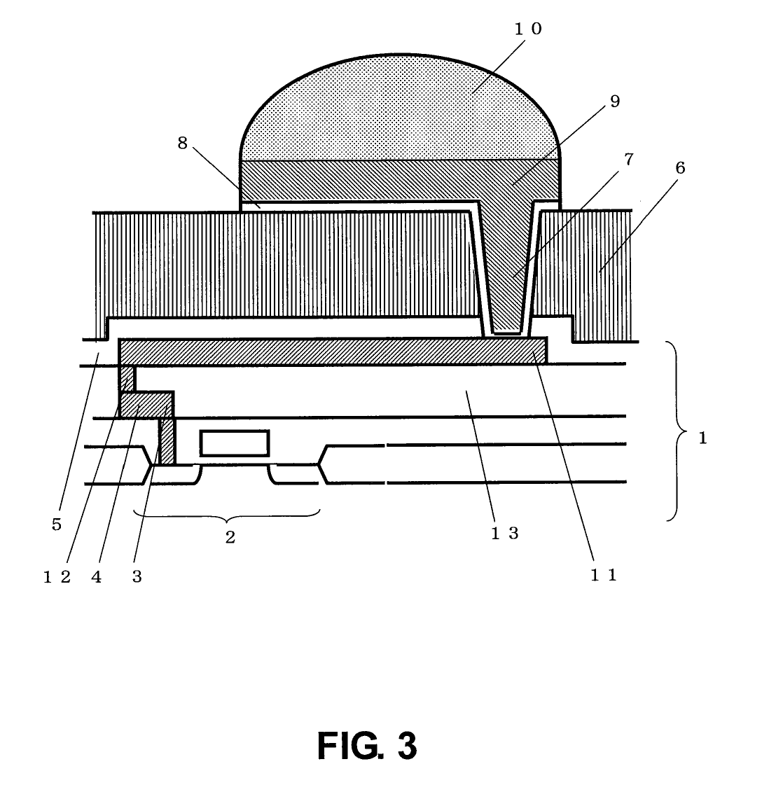

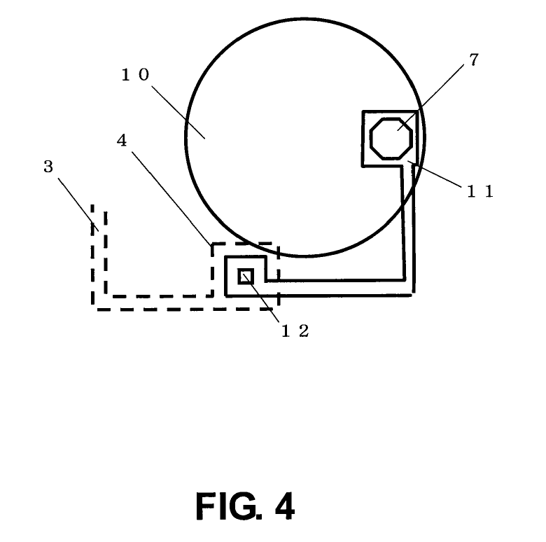

Then the case where the metal terminal 4 for input/output of the semiconductor element 2 is not located immediately below the bump electrode 10 is described with reference to FIGS. 3 and 4 illustrating a second embodiment.

The metal terminal 4 for input/output is covered by an insulating film 13 made of silicon oxide, and then a via 12 for metal wirings is formed. After that, a rewiring 11 that is made of aluminum and corresponds to a second metal wiring is formed. After that, the rewiring 11 is covered by the protection film 5 made of silicon nitride.

Next, the stress buffer layer 6 is formed on the protection film 5. In this embodiment, for the stress buffer layer 6, a photosensitive polyimide film is formed by spin coating to a thickness of approximately 20 micrometers. After that, a portion of the polyimide film to be the via-hole 7 is exposed and developed using a photomask, and a hole to be the via-hole 7 is formed in the polyimide film. The via-hole 7 is located so as to avoid a central part of a bump electrode to be formed later, specifically, located in a peripheral region below the bump electrode. After that, the protection film 5 is etched by sulfur hexafluoride with the polyimide film being used as a mask, to thereby expose the rewiring 11 that corresponds to the second metal wiring at a bottom of the via-hole 7. In this case, the via-hole 7 is opened not immediately above the semiconductor element 2 and the metal terminal 4 but above a position away from the semiconductor element 2 and the metal terminal 4.

In the above description, the thickness of the stress buffer layer 6 is set to approximately 20 micrometers. Alternatively, the thickness thereof may be, for example, 10 micrometers or 30 micrometers.

Further, the stress buffer layer 6 is not necessarily made of polyimide. For example, a resin containing an epoxy as a base resin, such as PMMR or SU-8 has a similar function. Further, polyimide or the resin containing an epoxy as a base resin does not necessarily need to be photosensitive. For example, the following method may be employed instead. The protection film 5 is covered by, for example, a polyimide film, and then a surface of the polyimide film is covered by a metal film such as a chromium film. A photoresist is applied on the chromium film to be formed into a pattern for a via-hole in plan view by using a photomask. After that, the chromium film covering the surface of the polyimide film is processed by etching into the pattern for the via-hole in plan view. The photoresist is removed, and then the chromium film is used as a mask for etching, to thereby process the polyimide film into a shape of the via-hole. Alternatively, the following method may also be employed. The protection film 5 is covered by a polyimide film, and then the polyimide film is half cured. A photoresist is applied on the half-cured polyimide film. Exposure and development are performed to form a pattern for a via-hole in the photoresist and the polyimide film simultaneously. After that, the photoresist is removed, and the via-hole is formed in the polyimide film.

Further, a ceramic film may be used for the stress buffer layer 6. In particular, aluminum oxide, aluminum nitride, and the like are effective in terms of dissipation of heat generated in the semiconductor element to the outside because the thermal conductivity thereof is higher than that of a resin such as polyimide. Since the mechanical strength of the ceramic film is, in addition, higher than that of the resin, it might be concluded that the ceramic film has a high usefulness for a material of a wafer level packaging.

The ceramic film may be formed by, for example, laminating ceramic fine particles on the surface of the protection film 5.

In the case of using the ceramic film for the stress buffer layer 6, the ceramic film may be formed directly on the protection film 5. Alternatively, the protection film 5 may be first covered by a resin, such as polyimide, having a mechanical rigidity lower than that of ceramics, and then the ceramic film may be formed thereon.

After the stress buffer layer 6 and the via-hole 7 are formed, an underlying metal film 8 made of titanium/tungsten and copper is formed by sputtering on a surface of the stress buffer layer 6, on an inner surface of the via-hole 7, and on the rewiring 11 that corresponds to the second metal wiring exposed at the bottom of the via-hole 7. After that, a photoresist is formed by spin coating on a surface of the underlying metal film 8. A part of the photoresist in a region in which a bump electrode 10 is to be formed is removed by exposure and development using a photomask, to thereby expose the underlying metal film 8. After that, copper is deposited out by electrolytic plating on an exposed part of the underlying metal film (underlying electrode) 8 to form a conductive layer 9. Next, a solder having a thickness of approximately 60 micrometers is formed by plating on the conductive layer 9 made of copper to serve as the bump electrode 10. Finally, the photoresist is dissolved and removed by an organic solvent, and then another part of the underlying metal film 8 exposed on the surface at this time is removed by etching to expose the stress buffer layer 6 in a region in which the bump electrode 10 is not formed. In this manner, the semiconductor device is completed. In this embodiment, as illustrated in FIG. 4, the metal terminal 4 is located so as not to overlap with the bump electrode 10, and hence the semiconductor device that is less likely to be damaged by external stress may be obtained.

What is claimed is:

1. A semiconductor device, comprising:
a semiconductor substrate;
a semiconductor element formed in the semiconductor substrate;
a metal wiring formed on the semiconductor element;
a protection film formed on the metal wiring, for protecting the metal wiring;
a stress buffer layer formed on the protection film;
a via-hole formed on the metal wiring through the protection film and the stress buffer layer;
an underlying metal film formed on an inner surface of the via-hole, on a surface of the metal wiring, and on a surface of the stress buffer layer;
a conductive layer formed on the underlying metal film, and filling the via-hole; and
a bump electrode formed on the conductive layer,
wherein the via-hole is disposed, in plan view, in a peripheral region below the bump electrode.

2. A semiconductor device according to claim 1, wherein the stress buffer layer comprises one of a polyimide film and an organic resin film containing an epoxy as a base resin.

3. A semiconductor device according to claim 1, wherein the stress buffer layer comprises an insulating ceramic film.

4. A semiconductor device according to claim 3, wherein the stress buffer layer comprises the ceramic film containing one of aluminum oxide and aluminum nitride.

5. A semiconductor device according to claim 3, wherein the stress buffer layer comprises two layers including the ceramic film and a film made of a material having a mechanical rigidity lower than a mechanical rigidity of the ceramic film.

6. A semiconductor device, comprising:
a semiconductor substrate;
a semiconductor element formed in the semiconductor substrate;
a first metal wiring formed on the semiconductor element;
a second metal wiring formed above the first metal wiring via an insulating film;
a protection film formed on the second metal wiring, for protecting the second metal wiring;
a stress buffer layer formed on the protection film;
a via-hole formed on the second metal wiring through the protection film and the stress buffer layer;
an underlying metal film formed on an inner surface of the via-hole, on a surface of the second metal wiring, and on a surface of the stress buffer layer;
a conductive layer formed on the underlying metal film, and filling the via-hole;
a bump electrode formed on the conductive layer; and
a metal terminal for input/output formed of the first metal wiring on the semiconductor element, wherein:
the second metal wiring includes a rewiring that connects the metal terminal with the bump electrode and the conductive layer formed in the via-hole, via a via formed on the metal terminal; and
the via-hole is disposed, in plan view, in a peripheral region below the bump electrode.

7. A semiconductor device according to claim 6, wherein the stress buffer layer comprises one of a polyimide film and an organic resin film containing an epoxy as a base resin.

8. A semiconductor device according to claim 6, wherein the stress buffer layer comprises an insulating ceramic film.

9. A semiconductor device according to claim 8, wherein the stress buffer layer comprises the ceramic film containing one of aluminum oxide and aluminum nitride.

10. A semiconductor device according to claim 8, wherein the stress buffer layer comprises two layers including the ceramic film and a film made of a material having a mechanical rigidity lower than a mechanical rigidity of the ceramic film.
